(19) United States
(12) Patent Application Publication
(10) Pub. No.: US 2011/0116900 A1
(43) Pub. Date: May 19, 2011

(54) SUBSTRATE ALIGNMENT APPARATUS

(75) Inventors: Tristan R. Holtam, Saratoga, CA (US); Keith B. Porthouse, Sunnyvale, CA (US); Vinay K. Shah, San Mateo, CA (US)

(73) Assignee: APPLIED MATERIALS, INC., Santa Clara, CA (US)

(21) Appl. No.: 12/948,111

(22) Filed: Nov. 17, 2010

Related U.S. Application Data
(60) Provisional application No. 61/262,231, filed on Nov. 18, 2009.

(51) Int. Cl. H01L 21/677; B65G 47/22; H01L 21/68; B65G 47/24

(52) U.S. Cl. 414/222.04; 414/754; 198/373

(57) ABSTRACT

Embodiments of the present invention generally relate to an apparatus and method for accurately aligning a plurality of substrates arranged in a planar array for batch processing. In one embodiment, the substrate alignment apparatus includes an array of oversized, recessed pockets for receiving the plurality of substrates. The substrate alignment apparatus may pick up the plurality of substrates from a location in which each substrate is not accurately positioned. Each pocket is configured at an angle from horizontal such that each substrate slides to a predefined corner of the pocket resulting in accurate alignment of each substrate. A vibration, tilting, directional brushes, or gas cushion may be provided to the substrate alignment apparatus to aid in low friction alignment of each substrate within its respective pocket. In one embodiment, the substrate alignment apparatus is an end effector for use on a transfer robot for use in a cluster-type processing system. In another embodiment, the substrate alignment apparatus is an alignment table for use in an in-line processing system.

### CROSS-REFERENCE TO RELATED APPLICATIONS

This application claims benefit of U.S. Provisional Patent Application Ser. No. 61/262,231 (APPM/014057L), filed Nov. 18, 2009, which is herein incorporated by reference.

### BACKGROUND OF THE INVENTION

1. Field of the Invention

Embodiments of the present invention generally relate to an apparatus and method for accurately aligning a plurality of substrates. Embodiments of the invention are particularly useful for aligning a plurality of substrates in a planar array for processing in the fabrication of crystalline silicon solar cells.

2. Description of the Related Art

Solar cells are photovoltaic devices that convert sunlight into electrical power. The most common solar cells are made from single or multicrystalline substrates, sometimes referred to as wafers, which are typically less than 0.3 mm thick. Solar cell fabrication processes require forming active regions in the substrate and forming current carrying metal lines on the substrates in batch processes. However, there are several issues with prior art manufacturing methods. For example, the formation processes are complicated multistep processes that require precise alignment for consistent and accurate movement and processing of the fragile solar cell substrates. Current state of the art apparatus and methods for ensuring precise alignment of substrates in batch solar cell processing include retaining the substrates in cassettes or carriers throughout the processing sequence. However, compatibility of the cassettes or carrier material with multiple processes becomes an issue. Other state of the art approaches for accurate and precise alignment use complex sensory systems to determine the exact position of wafers. However, these systems are expensive and are not ideally suited for vacuum processing systems.

Therefore, there exists a need for improved apparatus and methods for accurately aligning a batch of substrates during solar cell fabrication processes.

### SUMMARY OF THE INVENTION

In one embodiment of the present invention, a substrate alignment apparatus comprises a base member having a plurality of recessed pockets formed in an upper surface thereof and configured to receive a substrate in each pocket, wherein each pocket has a corner region formed by two intersecting wall members and a substantially planar substrate support surface, and wherein the corner region is positioned lower than the remainder of the substrate support surface.

In another embodiment of the present invention, a processing system comprises a load lock chamber configured to receive an array of substrates, one or more processing chambers configured to receive and process the array of substrates, a transfer chamber coupled to the load lock chamber and the one or more processing chambers, and a transfer robot disposed in the transfer chamber and having an end effector with a plurality of recessed pockets formed in an upper surface thereof, wherein the transfer robot is configured to pickup up an array of imprecisely aligned substrates from the load lock chamber, wherein each recessed pocket is configured to receive and align one of the plurality of substrates, and wherein the transfer robot is further configured to deliver the precisely aligned substrates to one of the one or more processing chambers.

In yet another embodiment of the present invention, a processing system comprises an input conveyor, a processing chamber, an outlet conveyor, and an alignment table disposed beneath the input conveyor, wherein the alignment table has a plurality of recessed pockets formed in an upper surface thereof, wherein the alignment table is configured to rise to receive an array of imprecisely positioned substrates from an upper surface of the input conveyor, wherein each recessed pocket is configured to receive and align one substrate from the array of substrates, and wherein the alignment table is further configured to lower to deliver the precisely aligned array of substrates back onto the input conveyor.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic, plan view of a substrate alignment apparatus according to one embodiment of the present invention.

FIG. 2 is a schematic, isometric view of the substrate alignment apparatus shown in FIG. 1.

FIG. 3A is a plan view of a recessed pocket of the substrate alignment apparatus designated as detail “3A” as shown in FIG. 1.

FIG. 3B is a schematic, cross-sectional view of the recessed pocket shown in FIG. 3A taken about the line 3B-3B.

FIG. 3C is a plan view of the recessed pocket depicted in FIG. 3A having a substrate positioned therein.

FIG. 4 is a plan view of a cluster-type processing system configured to process a batch of substrates arranged in a planar array.

FIG. 5 is a plan view of an in-line type processing system configured to process a batch of substrates arranged in a planar array.

For clarity, identical reference numerals have been used, where applicable, to designate identical elements that are common between figures. It is contemplated that features of one embodiment may be incorporated in other embodiments without further clarification.

### DETAILED DESCRIPTION

Embodiments of the present invention generally relate to an apparatus and method for accurately aligning a plurality of substrates arranged in a planar array for batch processing. In one embodiment, the substrate alignment apparatus includes an array of oversized, recessed pockets for receiving the plurality of substrates. The substrate alignment apparatus may pick up the plurality of substrates from a location in which each substrate is not accurately positioned. Each pocket is configured at an angle from horizontal such that each substrate slides to a predefined corner of the pocket resulting in accurate alignment of each substrate. A vibration, tilting, gas cushion, and/or directional brushes may be provided to the substrate alignment apparatus to aid in low friction alignment of each substrate within its respective pocket. In one embodiment, the substrate alignment apparatus is an end effector for use on a transfer robot for use in a cluster-type processing system. In another embodiment, the substrate alignment apparatus is an alignment table for use in an in-line processing system.

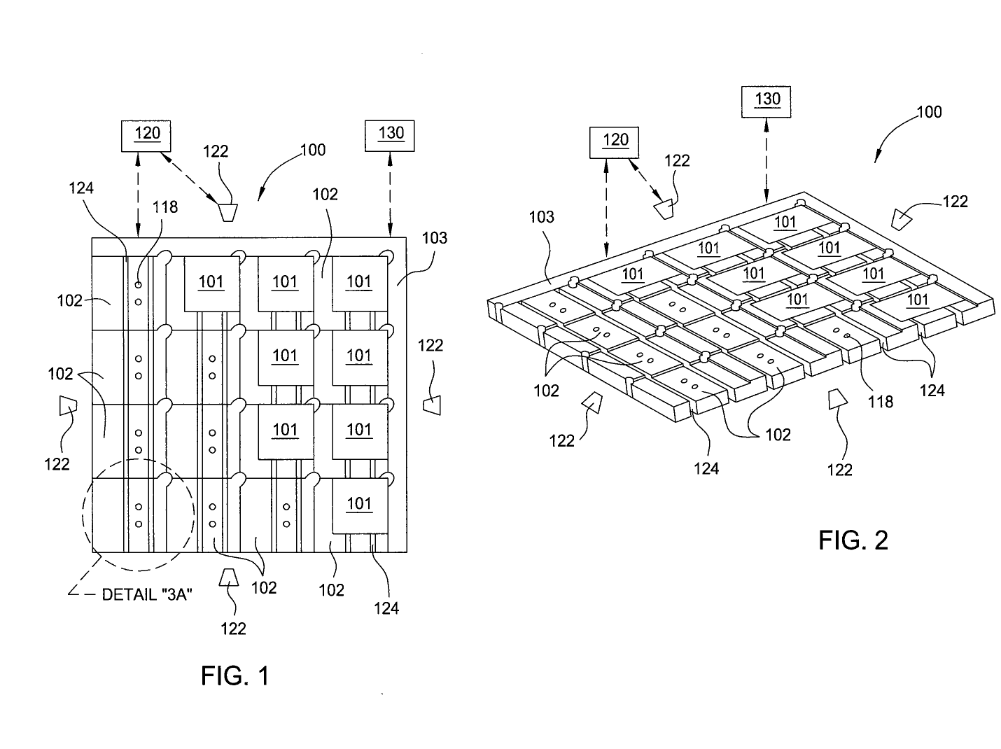

FIG. 1 is a schematic, plan view and FIG. 2 is a schematic, isometric view of substrate alignment apparatus 100 according to one embodiment of the present invention. For clarity, the substrate alignment apparatus 100 is depicted partially loaded with substrates 101. The substrate alignment apparatus 100 includes a base member 103 with an array of recessed pockets 102 defined therein and positioned to receive and align a plurality of substrates 101. The substrate alignment apparatus 100 has “m” rows of recessed pockets 102 by “n” columns of recessed pockets 102. The number of rows “m” of recessed pockets 102 may be between about 2 and about 10 or more, and the number of columns “n” may be between about 2 and about 10 or more. In one example, the number of rows “m” is 5, and the number of columns “n” is 6 for a total of 30 recessed pockets 102 configured to receive and align an array of 30 substrates 101. In another example, the number of rows “m” is 7, and the number of columns “n” is 7 for a total of 49 recessed pockets 102 configured to receive and align an array of 49 substrates 101.

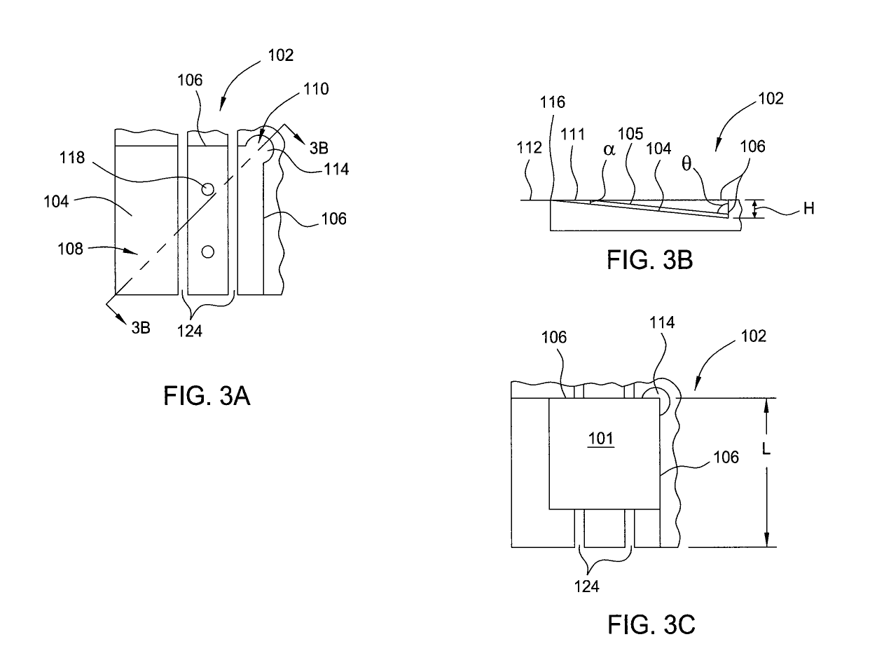

FIG. 3A is a plan view of one of the recessed pockets 102 of the substrate alignment apparatus 100 designated as detail “3A” as shown in FIG. 1. The recessed pocket 102 has a substrate receiving surface 104 bounded on two sides by wall members 106. The receiving surface 104 may be a substantially planar surface that is recessed at an angle from a first corner region 108 to an opposite corner region 110, which is positioned at the intersection of the wall members 106. Thus, the opposite corner region 110 is positioned lower than the remainder of the receiving surface 104. FIG. 3B is a schematic, cross-sectional view of the recessed pocket 102 shown in FIG. 3A taken about the line 3B-3B. The recessed pocket 102 is formed such that the substrate receiving surface 104 is configured at an acute angle α from a horizontal plane 112, which may substantially define an upper surface 111 of the substrate alignment apparatus 100. Each wall member 106 further forms an angle θ with the receiving surface 104. The angle θ may range from slightly less than 90 degrees to slightly greater than 90 degrees. The angle α is selected in accordance with such features of the substrate alignment apparatus 100 as the coefficient of friction of the receiving surface 104 such that a substrate 101 positioned within the recessed pocket 102 slides toward the corner region 110 until a corner of the substrate 101 is fully within the corner region 110, and two sides of the substrate 101 are respectively in contact with the wall members 106. The angle α may be between about 0° and about 10°.

As a result of the angle α of the receiving surface 104, the height of the wall members 106 may range from being substantially flush with the receiving surface at a point 116 to a maximum height “H” at the corner region. The maximum height “H” is selected such that it is at least slightly greater than the thickness of the substrate 101 to be received and aligned. The height “H” may be between about 0.5 mm and about 10 mm for a substrate 101 having a thickness of about 0.2 mm, for instance. This allows the substrate 101 to fully “seat” against the wall members 106 during the alignment process for consistently accurate alignment.

FIG. 3C is a plan view of the recessed pocket 102 depicted in FIG. 3A having a substrate 101 positioned therein. The corner region 110 may have a notch 114 formed therein. The notch 114 is generally an area of the corner region 110 wherein material of each of the wall members 106 is removed. The notch 114 allows the substrate 101 to slide into position without any contact between the fragile corner of the substrate 101 and the wall members 106. This prevents any impact loading of the corner of the substrate 101 which may lead to a damaged substrate 101.

As can be seen in FIGS. 1 and 3C, each recessed pocket 102 may be oversized with respect to the substrate 101 in order to allow the substrate alignment apparatus 100 to receive an array of substrates 101 that are not precisely positioned. The size of the recessed pocket 102 may thus be sized with respect to the size of the substrate 101 to be received and aligned by the substrate alignment apparatus 100. In general, the dimensions of the recessed pocket 102 may be between about 50 mm×50 mm and about 300 mm×300 mm in size. In one example, the recessed pocket 102 has dimensions corresponding to the length “L” of the wall members 106 ranging between about 150 mm and about 170 mm for a substrate having the dimensions 156 mm×156 mm, for instance.

The substrate alignment apparatus 100 may be made of a material substantially resistant to substrate processing conditions, particularly in situations where the substrate alignment apparatus 100 may be exposed to such conditions. In such situations, the substrate alignment apparatus 100 may be made of aluminum, carbon fiber, or a ceramic material such as Al₂O₃, ZrO₂, SiC, or SiN. In other situations where the substrate alignment apparatus 100 is not to be exposed to substrate processing conditions, the substrate alignment apparatus 100 can be made of other materials such as aluminum, steel, titanium, or plastic.

The receiving surface 104 of the substrate alignment apparatus 100 may have a low friction surface to readily allow the substrate 101 to slide into an alignment position wherein the corner of the substrate 101 is fully situated in the corner region 110 and edges of the substrate 101 are fully seated against the wall members 106. This may be provided by material selection and/or surface finish characteristics. For example, the coefficient of friction may be between about 0.01 and about 0.5.

As shown in FIG. 3B, the receiving surface 104 of the substrate alignment apparatus 100 may be covered with directional brush material 105 with a nap of fibers extending upwardly and toward the corner region 110. Vibrational movement may be applied to the alignment apparatus 100, as subsequently described, to aid movement of the substrate 101 in the direction of the fibers toward the corner region 110.

The alignment of each substrate 101 within the recessed pocket 102 may be aided by one or more additional devices or processes. For instance, as shown in FIGS. 1 and 2, apertures 118 may be formed through the substrate alignment apparatus 100 in the receiving surface 104 of each recessed pocket 102. The apertures 118 may be coupled to a gas source 120, which provides a slightly pressurized flow of gas through the apertures 118 to provide a “gas cushion” between the substrates 101 and the receiving surface 104. The gas cushion, in turn, reduces the contact between the bottom surface of the substrate 101 and the receiving surface 104, resulting in less friction between the respective surfaces. Thus, the “gas cushion” aids in the sliding of the substrate into its alignment position. In other embodiments, gas nozzles 122 may be coupled to the gas source 120 arranged on or near the substrate alignment apparatus 100 for urging the substrates 101 into their proper alignment position. The gas may be clean dry air (CDA), nitrogen gas, or oxygen gas, for example.

The substrate alignment apparatus 100 may be slightly tilted after receiving the substrates 101 in order to aid in the sliding of the substrates 101 into their proper alignment position via an actuator 130, such as a motor or the like. The substrate alignment apparatus 100 may be tilted at an angle between about 0.1° and about 20°. In addition to, or in lieu of the tilting of the substrate alignment apparatus 100, the substrate alignment apparatus 100 may be vibrated at a high frequency via the actuator 130 to aid in the sliding of the substrates 101 into their proper alignment position. The substrate alignment apparatus 100 may be vibrated at a frequency between about 0.50 Hz and about 10 kHz. The substrate alignment apparatus 100 may also be tilted or vibrated using one or more actuators described below.

Referring to FIGS. 1 and 2, the substrate alignment apparatus 100 may have channels 124 formed through the receiving surfaces 104 and wall members 106. In one example, the substrate alignment apparatus 100 has one or more channels 124 spanning the length of each column “n” of substrates 101 that are wide enough to allow the substrate alignment apparatus 100 to be raised through a plurality of conveyor belts having an array of substrates 101 positioned imprecisely thereon. In another example, the substrate alignment apparatus 100 has two or more channels 124 spanning the length of each column “n” of substrates 101 that are wide enough to allow substrate support elements, such as lift pins, to be extended through the channels to aid in transferring the array of substrates 101.

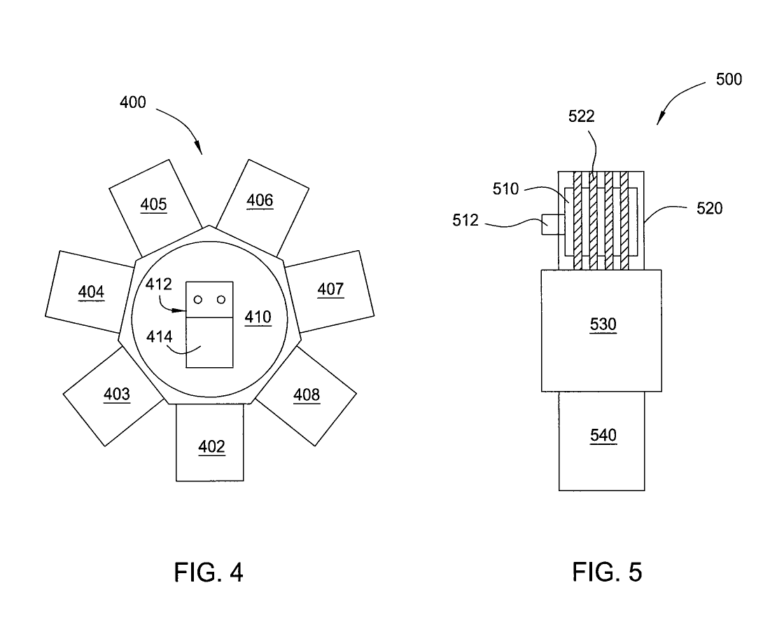

FIG. 4 is a plan view of a cluster-type processing system 400 configured to process a batch of substrates 101 arranged in a planar array. The processing system 400 incorporates the substrate alignment apparatus 100 as an end effector 414 on a transfer robot 412 positioned within a transfer chamber 410. The processing system 400 may also include a load lock chamber 402 and one or more processing chambers 403-408 coupled to the transfer chamber 410. The end effector 414 of the transfer robot 412 is configured to extend into each of the chambers (402-408) in order to retrieve an array of substrates 101 positioned imprecisely therein, accurately align the substrates 101 in the pockets 102 of the end effector 414, and transfer the array of substrates 101 into another chamber (402-408). The processing system 400 may be a portion of a larger production line configured to fabricate crystalline silicon solar cells, for instance.

The processing chambers 403-408 may be, for example, physical deposition (PVD) chambers, plasma enhanced chemical vapor deposition (PECVD) chambers, hot wire chemical vapor deposition (HWCVD) chambers, ion implant/doping chambers, plasma nitridation chambers, atomic layer deposition (ALD) chambers, plasma or vapor chemical etching chambers, laser anneal chambers, rapid thermal oxidation (RTO) chambers, rapid thermal nitridation (RTN) chambers, rapid thermal annealing (RTA) chambers, substrate reorientation chambers, vapor etching chambers, forming gas or hydrogen anneal chambers, plasma cleaning chambers, and/or other similar processing chambers.

In operation, an array of substrates 101 may first be placed on a substrates supporting surface of the load lock chamber 402. In one example, the substrates 101 are imprecisely placed by a substrate transfer robot (not shown). In another example, the substrates 101 are precisely placed in an array on the supporting surface of the load lock chamber 402, but the position of one or more substrates 101 is compromised during a process performed in the load lock chamber 402, such as pumping down the pressure within the load lock chamber 402 via a vacuum pump (not shown). The substrate supporting surface of the load lock chamber 402 may contain a plurality of lift pins on which the substrates 101 are supported during transfer processes.

A slit valve (not shown) separating the load lock chamber 402 from the transfer chamber 410 is opened, and the transfer robot 412 extends the end effector 414 into the load lock chamber 402. The end effector 414 is extended into the load lock chamber 402 such that the lift pins supporting the array of substrates 101 fit between the channels 124. Thus, the end effector 414 is extended beneath the array of substrates 101 such that each recessed pocket 102 is positioned beneath a respective substrate 101. In one example, the lift pins are then lowered, and each substrate 101 is received into a respective recessed pocket 102 of the end effector 414. In another example, the robot 412 raises the end effector 414 such that each substrate 101 is received into a respective recessed pocket 102 of the end effector 414 from the lift pins.

The frictional forces between each substrate 101 and its respective receiving surface 104 may be low enough that the substrate 101 readily slides into its alignment position as previously described. A light gas pressure may be supplied to each substrate 101 in order to urge the substrate 101 into its alignment position as previously described. Additionally, the entire end effector 414 may be slightly tilted by the transfer robot 412 using a rotational actuator, such as motor, to help urge the substrates 101 into their alignment positions as previously described.

Alternatively, the end effector 414 may be vibrated at a high frequency for a short period of time in order to help urge the substrates 101 into their alignment positions as previously described. In one example, the vibration is induced into the end effector 414 by the transfer robot 412 by way of an actuator run out of balance, such as an out of balance motor. In another example, the vibration is induced into the end effector 414 by the transfer robot 412 by way of a control scheme used to control the movement of the transfer robot 412, such as “gain scheduling” to temporarily destabilize the transfer robot 412 resulting in a vibrational load applied through the end effector 414.

The array of substrates 101 may then be transferred to one of the processing chambers, such as the processing chamber 403. The array of substrates 101 may be accurately aligned on the end effector 414 during the movement of the end effector 414 from within the load lock chamber 402 to within the processing chamber 403. The end effector 414 is then extended into the processing chamber 403 through an opened slit valve (not shown). The end effector 414 is extended into the processing chamber 403 such that each channel 124 is directly over a column of lift pins (not shown). The lift pins are then raised to receive the precisely positioned and aligned substrates 101 from the end effector 414. The precisely aligned array of substrates 101 are then placed on a substrate supporting surface within the processing chamber 403, and the substrates 101 are processed accordingly. In one example, a PECVD amorphous silicon deposition process is performed on the array of substrates 101 positioned in the processing chamber 403.

After performing the desired process on the array of substrates 101 in the processing chamber 403, the array of substrates 101 are removed from the processing chamber 403 via the end effector 414 and robot 412. Since the positioning of one or more of the substrates 101 may have been compromised during processing, the end effector 414 is extended into the processing chamber 403 such that each recessed pocket 102 is beneath a corresponding substrate 101. The lift pins are lowered, and each substrate 101 is received into a respective recessed pocket 102 of the end effector 414. As with the process described with respect to transfer from the load lock chamber 402, the substrates 101 are accurately and precisely aligned on the end effector 414 during a subsequent transfer operation.

The array of substrates 101 are then transferred into one or more of the remaining processing chambers 404-408 for subsequent processing operations. In one example, a metallization type deposition process is performed on the precisely positioned array of substrates 101 in a subsequent operation. Finally, the array of substrates 101 is transferred back to the load lock chamber 402 in preparation for exiting the system 400. Thus, the end effector 414 incorporating the substrate alignment apparatus 100 is capable of receiving an imprecisely aligned array of substrates 101 and accurately and precisely aligning them during transfer to the next location in the cluster-type processing system 400.

FIG. 5 is a plan view of an in-line type processing system 500 configured to process a batch of substrates 101 arranged in a planar array. The processing system 500 incorporates the substrate alignment apparatus 100 as an alignment table 510 positioned beneath an incoming conveyor 520. The processing system 500 may further include at least one processing chamber 530 for processing the batch of substrates 101 and an outgoing conveyor 540 for transporting the processed array of substrates 101 out of the processing system 500. The processing system 500 may be a portion of a larger production line configured to fabricate crystalline silicon solar cells, for example.

An array of substrates 101 is transported from a downstream process module into the processing system 500 on the incoming conveyor 520. The incoming conveyor 520 may include a plurality of belts 522 driven by a plurality of rollers (not shown) and actuators (not shown) as used in conventional conveying systems. The array of substrates 101 may be imprecisely positioned on the incoming conveyor 520 due to slight movements during previous processing chambers or during the during the process of transferring the array of substrates 101 between a downstream processing chamber and the processing chamber 530.

The alignment table 510 may be located just beneath the upper surface of the incoming conveyor 520 just downstream from the processing chamber 530. The incoming conveyor 520 may transfer the array of substrates 101 to a position wherein each substrate 101 is located above a respective recessed pocket 102 in the alignment table 510. Once the substrates 101 are roughly aligned above the recessed pockets 102, the alignment table 510 is raised via one or more actuators, such as motors or cylinders, such that each substrate 101 is raised off of the conveyor belts 522 and seats within the respective recessed pocket 102. The channels 124 formed through the alignment table 510 are aligned with the conveyor belts 522 so that the alignment table 510 may be raised above the upper surface of the input conveyor 510 during the alignment process.

Once each substrate 101 is in contact with the respective receiving surface 104, the substrate 101 is urged into its proper alignment position as described above. The frictional forces between each substrate 101 and its respective receiving surface 104 may be sufficiently low so that the substrate 101 readily slides into its alignment position as previously described. A light gas pressure may be supplied to each substrate 101 in order to urge the substrate into its alignment position as previously described. The entire alignment table 510 may be slightly tilted by the actuators 512, such as motor, to help urge the substrates 101 into their alignment positions as previously described.

Alternatively, the alignment table 510 may be vibrated at a high frequency for a short period of time in order to help urge the substrates 101 into their alignment positions as previously described. In one example, the vibration is induced into the alignment table 510 by the actuators 512 by way of an actuator run out of balance, such as an out of balance motor. In another example, the vibration is induced into the alignment table by the actuators 512 by way of a control scheme used to control the movement of the alignment table 510, such as “gain scheduling” to temporarily destabilize the alignment table 510 resulting in a vibrational load applied to the alignment table 510.

Once the array of substrates 101 are fully seated against the wall members 106 and precisely positioned on the alignment table 510, the alignment table 510 is lowered such that the precisely positioned array of substrates are replaced onto the input conveyor 510 just prior to entry into the processing chamber 530. Next, the precisely aligned substrates 101 are transferred into the processing chamber 530 for desired processing. In one example, a PECVD amorphous silicon deposition process is performed on the array of substrates 101 positioned in the processing chamber 530. In another example, a metallization type deposition process is performed on the precisely positioned array of substrates 101 in the processing chamber 530. Finally, the array of substrates 101 are transported out of the processing chamber 530 and onto the output conveyor 540 where they are removed from the processing system 500. Thus, the substrate alignment apparatus 100 may be used as an alignment table 510 for precisely and accurately positioning an array of substrates 101 for processing in the in-line processing system 500.

While the foregoing is directed to embodiments of the present invention, other and further embodiments of the invention may be devised without departing from the basic scope thereof, and the scope thereof is determined by the claims that follow.

1. A substrate alignment apparatus, comprising:
a base member having a plurality of recessed pockets formed in an upper surface thereof and configured to receive a substrate in each pocket, wherein each pocket has a corner region formed by two intersecting wall members and a substantially planar substrate support surface, and wherein the corner region is positioned lower than the remainder of the substrate support surface.

2. The substrate alignment apparatus of claim 1, wherein the two wall members that define each pocket have a notch of material removed from each of them at the intersection of the two wall members.

3. The substrate alignment apparatus of claim 1, wherein the recessed pockets are arranged in an array having a plurality of rows and a plurality of columns, and wherein at least one channel is formed through the base member within each column and substantially spanning the length of the column.

4. The substrate alignment apparatus of claim 1, further comprising a gas source in fluid communication with a plurality of apertures disposed through the substrate support surfaces.

5. The substrate alignment apparatus of claim 1, further comprising:
a plurality of gas nozzles directed toward the recessed pockets; and
a gas source in fluid communication with the gas nozzles.

6. The substrate alignment apparatus of claim 1, further comprising an actuator configured to apply a high frequency vibration load to the apparatus.

7. The substrate alignment apparatus of claim 1, further comprising an actuator configured to tilt the apparatus.

8. The substrate alignment apparatus of claim 1, wherein each substrate support surface has a directional brush material disposed thereon.

9. A processing system, comprising:
a load lock chamber configured to receive an array of substrates;
one or more processing chambers configured to receive and process the array of substrates;
a transfer chamber coupled to the load lock chamber and the one or more processing chambers; and
a transfer robot disposed in the transfer chamber and having an end effector with a plurality of recessed pockets formed in an upper surface thereof, wherein the transfer robot is configured to pickup up an array of imprecisely aligned substrates from the load lock chamber, wherein each recessed pocket is configured to receive and align one of the plurality of substrates, and wherein the transfer robot is further configured to deliver the precisely aligned substrates to one of the one or more processing chambers.

10. The processing system of claim 9, wherein each pocket has a corner region formed by two intersecting wall members and a substantially planar substrate support surface, and wherein the corner region is positioned lower than the remainder of the substrate support surface.

11. The processing system of claim 10, wherein each recessed pocket has a notch of material removed from each wall member at the intersection of the two wall members.

12. The processing system of claim 11, wherein the recessed pockets are arranged in an array having a plurality of rows and a plurality of columns and wherein at least two channels are formed through the end effector within each column and substantially spanning the length of the column.

13. A processing system, comprising:
an incoming conveyor;
a processing chamber;
an outgoing conveyor; and
an alignment table disposed beneath the incoming conveyor, wherein the alignment table has a plurality of recessed pockets formed in an upper surface thereof, wherein the alignment table is configured to rise to receive an array of imprecisely positioned substrates from an upper surface of the incoming conveyor, wherein each recessed pocket is configured to receive and align one substrate from the array of substrates, and wherein the alignment table is further configured to lower to deliver the precisely aligned array of substrates back onto the incoming conveyor.

14. The processing system of claim 13, wherein each pocket has a corner region formed by two intersecting wall members and a substantially planar substrate support surface, and wherein the corner region is positioned lower than the remainder of the substrate support surface.

15. The processing system of claim 14, wherein each recessed pocket has a notch of material removed from each wall member at the intersection of the two wall members.

16. The processing system of claim 15, wherein the recessed pockets are arranged in an array having a plurality of rows and a plurality of columns and wherein at least one channel is formed through the end effector within each column and substantially spanning the length of each column.

17. The processing system of claim 16, further comprising:
a plurality of gas nozzles directed toward the recessed pockets; and
a gas source in fluid communication with the gas nozzles.

18. The processing system of claim 16, further comprising an actuator configured to apply a high frequency vibration load to the alignment table.

19. The processing system of claim 16, further comprising a gas source in fluid communication with a plurality of apertures formed in the substrate support surfaces.

20. The processing system of claim 16, wherein each substrate support surface has a directional brush material disposed thereover.
